(19) United States
(12) Patent Application Publication
(10) Pub. No.: US 2024/0324417 A1
(43) Pub. Date: Sep. 26, 2024

(54) DISPLAY DEVICE

(71) Applicant: Samsung Display Co., LTD., Yongin-si (KR)

(72) Inventors: DAEWON KIM, Yongin-si (KR); JONGHO SON, Yongin-si (KR); Hyebeom Shin, Yongin-si (KR); KYUNGHEE LEE, Yongin-si (KR); JINHYEONG LEE, Yongin-si (KR); SUN-YOUNG CHANG, Yongin-si (KR)

(21) Appl. No.: 18/411,147

(22) Filed: Jan. 12, 2024

(30) Foreign Application Priority Data
Mar. 20, 2023 (KR) 10-2023-0035738

(51) Int. Cl. H10K 59/80; G02F 1/1333; G02F 1/1335; G02F 1/1337; G02F 1/1339; H10K 59/50

(52) U.S. Cl. CPC H10K 59/8791; G02F 1/133371; G02F 1/133502; G02F 1/133504; G02F 1/133738; G02F 1/133742; G02F 1/1339; H10K 59/50

(57) ABSTRACT

A display device includes: a first substrate, a display portion disposed on the first substrate, a second substrate disposed on the display portion, and a liquid crystal layer contacting one surface of the second substrate, including a plurality of liquid crystal molecules, where a surface of the liquid crystal layer facing the first substrate has a concavo-convex shape.

This application claims priority to Korean Patent Application No. 10-2023-0035738, filed on Mar. 20, 2023, and all the benefits accruing therefrom under 35 U.S.C. § 119, the content of which in its entirety is herein incorporated by reference.

### BACKGROUND

### 1. Field

Embodiments provide generally to a display device. More particularly, embodiments relate to a display device that provides visual information.

### 2. Description of the Related Art

As information technology develops, the importance of display devices, which are communication media between users and information, is being highlighted. Accordingly, the display devices such as a liquid crystal display device, an organic light emitting display device, a plasma display device, and the like are more widely used in various fields.

### SUMMARY

Embodiments provide a display device with improved display quality.

A display device according to embodiments of the disclosure includes a first substrate, a display portion disposed on the first substrate, a second substrate disposed on the display portion, and a liquid crystal layer contacting one surface of the second substrate, including a plurality of liquid crystal molecules. In such embodiments, a surface of the liquid crystal layer facing the first substrate has a concavo-convex shape.

In an embodiment, the plurality of liquid crystal molecules may be vertically aligned with respect to the one surface of the second substrate.

In an embodiment, the plurality of liquid crystal molecules may be randomly aligned horizontally with respect to the one surface of the second substrate.

In an embodiment, the display device may further include a sealing portion disposed between the first substrate and the second substrate along an edge of each of the first substrate and the second substrate, where the sealing portion may couple the first substrate and the second substrate to each other.

In an embodiment, each of the first substrate and the second substrate may include a glass substrate.

In an embodiment, an average thickness of the liquid crystal layer may be in a range from about 1000 nanometers (nm) to about 3000 nm.

A display device according to embodiments of the disclosure includes a first substrate, a display portion disposed on the first substrate, a second substrate disposed on the display portion, and a scattering layer contacting one surface of the second substrate.

In an embodiment, the scattering layer may include a base resin and a plurality of scattering particles dispersed in the base resin.

In an embodiment, a surface of the scattering layer facing the first substrate may be substantially flat.

In an embodiment, a surface of the scattering layer facing the first substrate may have a concavo-convex shape.

In an embodiment, the scattering layer may include a base resin and a plurality of scattering particles dispersed in the base resin, and a surface of the scattering layer facing the first substrate may have a concavo-convex shape.

In an embodiment, the scattering layer may include an organic material having light transmittance.

In an embodiment, the display device may further include a sealing portion disposed between the first substrate and the second substrate along an edge of each of the first substrate and the second substrate, where the sealing portion may couple the first substrate and the second substrate to each other.

In an embodiment, each of the first substrate and the second substrate may include a glass substrate.

A display device according to embodiments of the disclosure includes a first substrate, a display portion disposed on the first substrate, a second substrate disposed on the display portion, and a low-reflection layer contacting one surface of the second substrate, where the low-reflection layer has a multi-layer structure in which a plurality of sub-layers are stacked.

In an embodiment, the low-reflection layer may have a multi-layer structure including two or three sub-layers.

In an embodiment, the sub-layers of the low-reflection layer may have different refractive indices from each other.

In an embodiment, a refractive index of each of the sub-layers of the low-reflection layer may be in a range from about 1.0 to about 1.9.

In an embodiment, a thickness of each of the sub-layers of the low-reflection layer may be in a range from about 10 nm and about 900 nm.

In an embodiment, the low-reflection layer may include at least one material selected from an inorganic material and an organic material having light transmittance.

In a display device according to embodiments of the disclosure, any one of a liquid crystal layer, a scattering layer, and a low reflection layer may be disposed between a first substrate and a second substrate. Accordingly, in such embodiments, coherence can be reduced, such that the visibility of rainbow stains in a display area can be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the disclosure.

FIG. 2 is a cross-sectional view taken along line I-I′ of FIG. 1.

FIGS. 3 and 4 are cross-sectional views illustrating region A of FIG. 2 according to embodiments of the disclosure.

FIGS. 5, 6, and 7 are cross-sectional views illustrating area A of FIG. 2 according to alternative embodiments of the disclosure.

FIGS. 8 and 9 are cross-sectional views illustrating area A of FIG. 2 according to other alternative embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or in “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device according to embodiments of the disclosure will be described in detail with reference to the accompanying drawings. The same reference numerals are used for the same components in the drawings, and any repetitive detailed descriptions of the same components will be omitted or simplified.

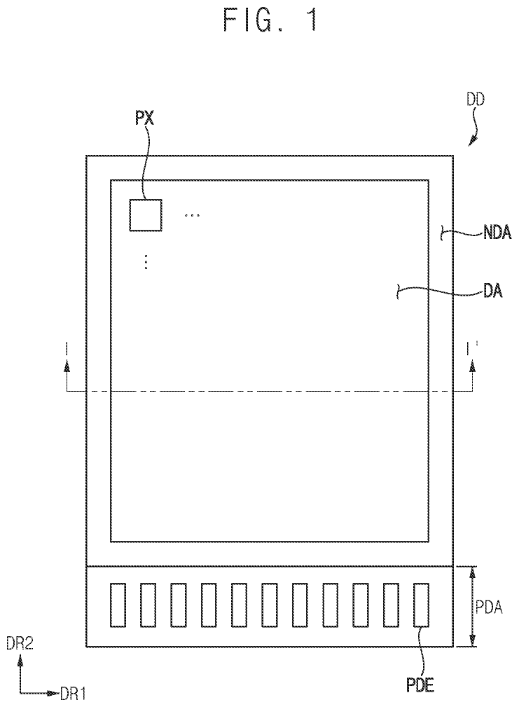

FIG. 1 is a plan view illustrating a display device according to an embodiment of the disclosure.

Referring to FIG. 1, a display device DD according to an embodiment may include a display area DA and a non-display area NDA. The display area DA may be an area capable of displaying an image by generating light or adjusting transmittance of light provided from an external light source. The non-display area NDA may be an area in which no image is displayed. The non-display area NDA may be positioned around the display area DA. In an embodiment, for example, the non-display area NDA may entirely surround the display area DA.

A plurality of pixels PX may be disposed in the display area DA. The plurality of pixels PX may be arranged in a matrix form along a first direction DR1 and a second direction DR2 crossing the first direction DR1. Each of the plurality of pixels PX may emit light. As each of the plurality of pixels PX emits light, the display area DA may display an image.

Lines connected to the plurality of pixels PX may be further disposed in the display area DA. In an embodiment, for example, the lines may include a data signal line, a gate signal line, and a power line.

Drivers for driving the plurality of pixels PX may be disposed in the non-display area NDA. In an embodiment, for example, the drivers may include a gate driver, a light emitting driver, a power voltage generator, a timing controller, and the like. The plurality of pixels PX may emit light based on signals transmitted from the drivers.

The non-display area NDA may include a pad area PDA. The pad area PDA may be spaced apart from one side of the display area DA. In an embodiment, for example, the pad area PDA may have a shape extending in the first direction DR1.

A plurality of pad electrodes PDE may be disposed in the pad area PDA. The lines may be electrically connected between the plurality of pad electrodes PDE and the plurality of pixels PX. The plurality of pad electrodes PDE may be disposed to be spaced apart from each other in the first direction DR1. In an embodiment, for example, each of the plurality of pad electrodes PDE may include a metal, an alloy, a metal nitride, a conductive metal oxide, a transparent conductive material, or the like. These may be used alone or in combination with each other.

In the specification, a plane may be defined as the first direction DR1 and the second direction DR2 crossing the first direction DR1. In an embodiment, for example, the first direction DR1 may be perpendicular to the second direction DR2.

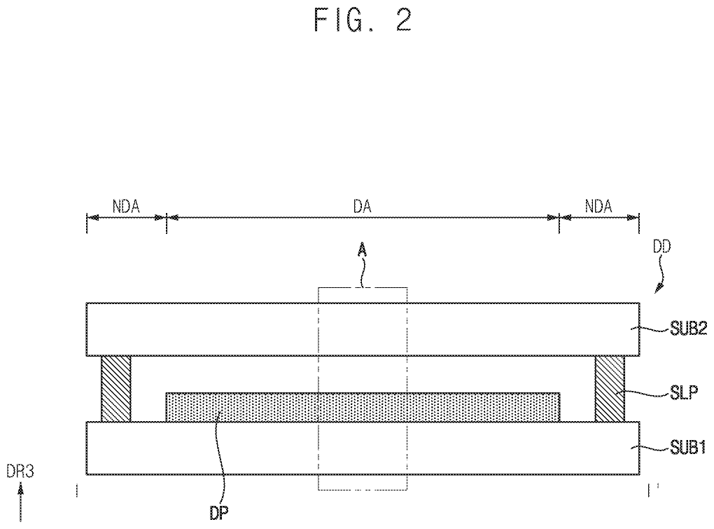

FIG. 2 is a cross-sectional view taken along line I-I′ of FIG. 1.

Referring to FIG. 2, the display device DD according to an embodiment of the disclosure may include a first substrate SUB1, a display portion DP, a sealing portion SLP, and a second substrate SUB2.

The first substrate SUB1 may include a transparent material or an opaque material. In an embodiment, for example, the first substrate SUB1 may include a rigid glass substrate, a polymer substrate, a flexible film, a metal substrate, or the like. These may be used alone or in combination with each other. In an embodiment, the first substrate SUB1 may include a rigid glass substrate.

The display portion DP may be disposed on the first substrate SUB1. The display portion DP may overlap the display area DA in a thickness direction of the display device or the first substrate SUB1 (or a third direction DR3). The display portion DP may include various elements. In an embodiment, for example, the display portion DP may include an organic light emitting element. Alternatively, the display portion DP may include a liquid crystal element. Detailed features of the display portion DP will be described later.

The second substrate SUB2 may be disposed on the first substrate SUB1. The second substrate SUB2 may face the first substrate SUB1. The second substrate SUB2 may protect the display portion DP from external impact by covering the display portion DP disposed on the first substrate SUB1.

The second substrate SUB2 may include a transparent material or an opaque material. In an embodiment, for example, the second substrate SUB2 may include a rigid glass substrate, a polymer substrate, a flexible film, a metal substrate, or the like. These may be used alone or in combination with each other. In an embodiment, the second substrate SUB2 may include a rigid glass substrate.

The sealing portion SLP may be disposed along an edge of each of the first and second substrates SUB1 and SUB2 between the first and second substrates SUB1 and SUB2. In an embodiment, the sealing portion SLP may be disposed to surround the display portion DP. The first substrate SUB1 and the second substrate SUB2 may be coupled by the sealing portion SLP. As a space between the first substrate SUB1 and the second substrate SUB2 is sealed by the sealing part SLP, permeation of external moisture, air, impurities, or the like into the display portion DP disposed in the space may be effectively prevented. In an embodiment, for example, the sealing portion SLP may include an organic material such as epoxy resin and the like.

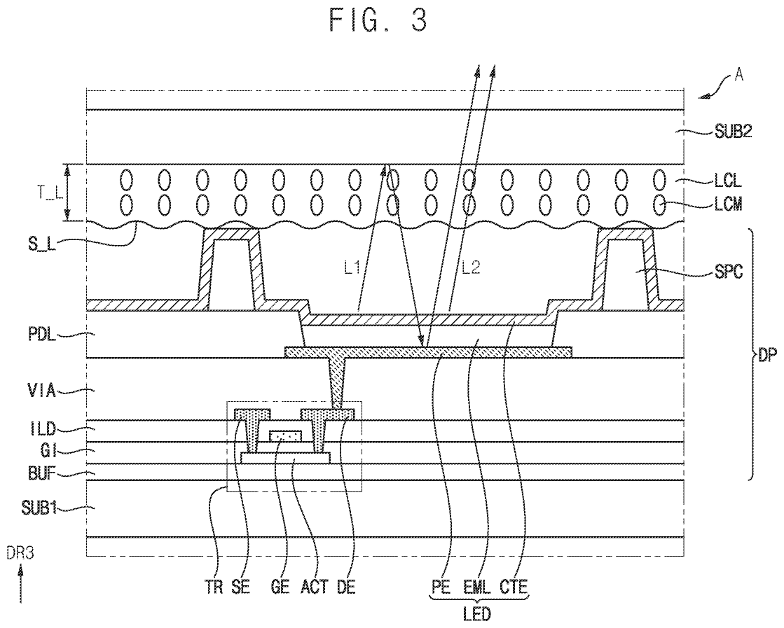

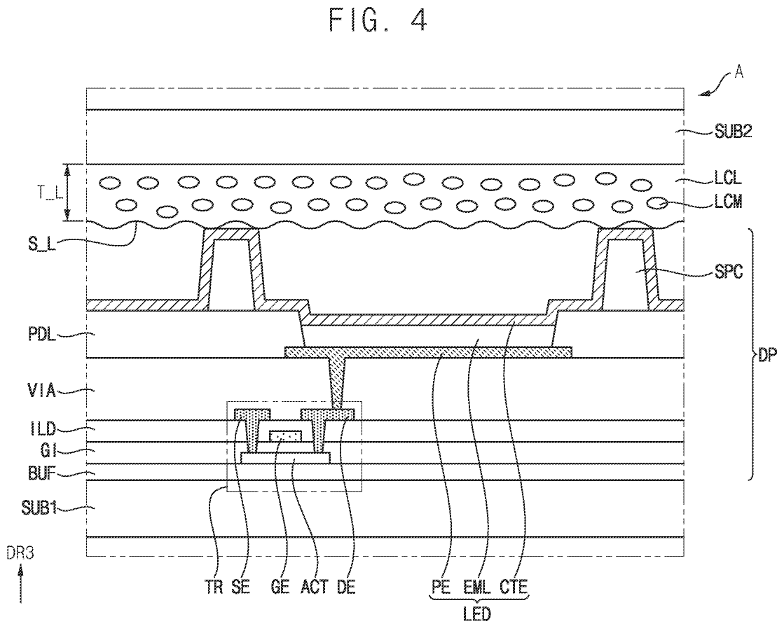

FIGS. 3 and 4 are cross-sectional views illustrating region A of FIG. 2 according to embodiments of the disclosure.

Referring to FIGS. 2, 3, and 4, the display device DD according to an embodiment of the disclosure may include the first substrate SUB1, the display portion DP, a liquid crystal layer LCL, and the second substrate SUB2. In such an embodiment, the display portion DP may include a buffer layer BUF, a transistor TR, a gate insulating layer GI, an interlayer insulating layer ILD, a via insulating layer VIA, a pixel defining layer PDL, and a light emitting element LED, and a spacer SPC.

In such an embodiment, the transistor TR may include an active pattern ACT, a gate electrode GE, a source electrode SE, and a drain electrode DE, and the light emitting element LED may include a pixel electrode PE, a light emitting layer EML, and a common electrode CTE.

The buffer layer BUF may be disposed on the first substrate SUB1. The buffer layer BUF may prevent diffusion of metal atoms or impurities from the first substrate SUB1 into the transistor TR. In addition, the buffer layer BUF may improve the flatness of the surface of the first substrate SUB1 in a case where the surface of the first substrate SUB1 is not uniform. In an embodiment, for example, the buffer layer BUF may include an inorganic material such as silicon oxide (SiOₓ), silicon nitride (SiNₓ), silicon oxynitride (SiOₓN_{y}), or the like. These may be used alone or in combination with each other.

The active pattern ACT may be disposed on the buffer layer BUF. The active pattern ACT may include a metal oxide semiconductor, an inorganic semiconductor (e.g., amorphous silicon, poly silicon), or an organic semiconductor. The active pattern ACT may have a source region, a drain region, and a channel region positioned between the source region and the drain region.

The metal oxide semiconductor may include a two-component compound (ABₓ), a ternary compound (ABₓC_{y}), a four-component compound (ABₓC_{y}D_{z}), or the like containing indium (In), zinc (Zn), gallium (Ga), tin (Sn), titanium (Ti), aluminum (Al), hafnium (Hf), zirconium (Zr), magnesium (Mg), or the like. In an embodiment, for example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), or the like. These may be used alone or in combination with each other.

The gate insulating layer GI may be disposed on the buffer layer BUF. The gate insulating layer GI may sufficiently cover the active pattern ACT, and may have a substantially flat upper surface without creating a step around the active pattern ACT. Alternatively, the gate insulating layer GI may cover the active pattern ACT and may be disposed along the profile of the active pattern ACT to have a uniform thickness. In an embodiment, for example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The gate electrode GE may be disposed on the gate insulating layer GI. The gate electrode GE may overlap the channel region of the active pattern ACT in the third direction DR3. The gate electrode GE may include a metal, an alloy metal nitride, a conductive metal oxide, a transparent conductive material, or the like.

Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. In addition, examples of the metal nitride may include aluminum nitride (AlNₓ), tungsten nitride (WNₓ), chromium nitride (CrNₓ), or the like. These may be used alone or in combination with each other.

The interlayer insulating layer ILD may be disposed on the gate insulating layer GI. The interlayer insulating layer ILD may sufficiently cover the gate electrode GE, and may have a substantially flat upper surface without creating a step around the gate electrode GE. Alternatively, the interlayer insulating layer ILD may cover the gate electrode GE and may be disposed along the profile of each gate electrode GE to have a uniform thickness. In an embodiment, for example, the interlayer insulating layer (ILD) may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The source electrode SE and the drain electrode DE may be disposed on the interlayer insulating layer ILD. The source electrode SE may be connected to the source region of the active pattern ACT through a first contact hole defined or formed through a first part of the gate insulating layer GI and the interlayer insulating layer ILD. In addition, the drain electrode DE may be connected to the drain region of the active pattern ACT through a second contact hole defined or formed through a second part of the gate insulating layer GI and the interlayer insulating layer ILD. In an embodiment, for example, each of the source electrode SE and the drain electrode DE may include a metal, an alloy, a metal nitride, a conductive metal oxide, a transparent conductive material, or the like. These may be used alone or in combination with each other.

Accordingly, the transistor TR including the active pattern ACT, the gate electrode GE, the source electrode SE, and the drain electrode DE may be disposed on the first substrate SUB1.

The via insulating layer VIA may be disposed on the interlayer insulation layer ILD. The via insulating layer VIA may sufficiently cover the source electrode SE and the drain electrode DE. The via insulating layer VIA may include an organic material. In an embodiment, for example, the via insulating layer VIA may include phenolic resin, polyacrylates resin, polyimides rein, polyamides resin, siloxane resin, epoxy resin, or the like. These may be used alone or in combination with each other.

The pixel electrode PE may be disposed on the via insulating layer VIA. The pixel electrode PE may be connected to the drain electrode DE through a contact hole defined or formed through the via insulating layer VIA. In an embodiment, for example, the pixel electrode PE may include a metal, an alloy, a metal nitride, a conductive metal oxide, a transparent conductive material, or the like. These may be used alone or in combination with each other. The pixel electrode PE may operate as an anode.

The pixel defining layer PDL may be disposed on the via insulating layer VIA. The pixel defining layer PDL may cover an edge of the pixel electrode PE. In addition, a pixel opening exposing at least a part of an upper surface of the pixel electrode PE may be defined in the pixel defining layer PDL. In an embodiment, for example, the pixel defining layer PDL may include an inorganic material and/or an organic material. In an embodiment, the pixel defining layer PDL may include an organic material such as an epoxy resin, a siloxane resin, or the like. These may be used alone or in combination with each other. In an alternative embodiment, the pixel defining layer PDL may include an inorganic material and/or an organic material including a light blocking material having a black color.

The spacer SPC may be disposed on the pixel defining layer PDL. Specifically, the spacer SPC may protrude from the upper surface of the pixel defining layer PDL in the thickness direction (e.g., in the third direction DR3). The spacer SPC may maintain a gap between the first substrate SUB1 and the second substrate SUB2. The spacer SPC may prevent display characteristics from deteriorating due to external impact. In addition, the spacer SPC may serve to support a fine metal mask (“FMM”) used to deposit an organic light emitting material. In an embodiment, for example, the spacer SPC may include an inorganic material and/or an organic material.

In an embodiment, for example, the spacer SPC may be formed through a process separate from the pixel defining layer PDL. Alternatively, the spacer SPC may be simultaneously formed through a same process as the pixel defining layer PDL.

The light emitting layer EML may be disposed on the pixel electrode PE. In an embodiment, the light emitting layer EML may be disposed inside the pixel opening of the pixel defining layer PDL. The light emitting layer EML may include an organic light emitting material that emits light of a preset color. In an embodiment, for example, the light emitting layer EML may include an organic light emitting material that emits red light, green light, or blue light.

The common electrode CTE may be disposed on the light emitting layer EML, the pixel defining layer PDL, and the spacer SPC. In an embodiment, for example, the common electrode CTE may include a metal, an alloy, a metal nitride, a conductive metal oxide, a transparent conductive material, or the like. These may be used alone or in combination with each other. The common electrode CTE may operate as a cathode.

Accordingly, the light emitting element LED including the pixel electrode PE, the light emitting layer EML, and the common electrode CTE may be disposed on the first substrate SUB1. The light emitting element LED may be electrically connected to the transistor TR.

In an embodiment, the liquid crystal layer LCL including a plurality of liquid crystal molecules LCM may be disposed between the display portion DP and the second substrate SUB2. In such an embodiment, the liquid crystal layer LCL may contact one surface of the second substrate SUB2. The one surface of the second substrate SUB2 may face the first substrate SUB1.

In an embodiment, a surface S_L of the liquid crystal layer LCL facing the first substrate SUB1 may have a concavo-convex shape. That is, the surface S_L of the liquid crystal layer LCL may not be flat. In an embodiment, for example, the one surface of the second substrate SUB2 may be coated with the liquid crystal layer LCL, and the surface S_L of the liquid crystal layer LCL may have a concavo-convex shape provided or formed through an etching process, an ashing process, or a plasma process.

In an embodiment, as illustrated in FIG. 3, the plurality of liquid crystal molecules LCM may be vertically aligned with respect to the second substrate SUB2. In such an embodiment, the degree of orientation of the plurality of liquid crystal molecules LCM may be close to about 1. In an alternative embodiment, as illustrated in FIG. 4, the plurality of liquid crystal molecules LCM may be randomly aligned horizontally with respect to the second substrate SUB2. In such an embodiment, the degree of orientation of the plurality of liquid crystal molecules LCM may be about 0.5 or less. When the plurality of liquid crystal molecules LCM are randomly aligned horizontally, a scattering effect can be obtained.

In an embodiment, for example, an alignment layer may be disposed on and/or under the liquid crystal layer LCL, and the plurality of liquid crystal molecules LCM may be vertically aligned or randomly horizontally aligned through the alignment layer. Alternatively, the plurality of liquid crystal molecules LCM may be vertically aligned or randomly horizontally aligned by forming the liquid crystal layer LCL on one surface of the second substrate SUB2, positioning the liquid crystal layer LCL between separately prepared electrodes, and applying an electric field to the liquid crystal layer LCL. However, embodiments of the disclosure are not limited thereto, and the plurality of liquid crystal molecules LCM may be vertically aligned or randomly horizontally aligned through various methods.

In an embodiment, for example, an average thickness T_L of the liquid crystal layer LCL may be in a range from about 1000 nanometers (nm) to about 3000 nm. However, embodiments of the disclosure are not limited thereto.

Among the lights emitted from the light emitting element LED, a first light L1 may be reflected from the second substrate SUB2 and incident on the pixel electrode PE, and the first light L1 incident on the pixel electrode PE may be reflected again and pass through the second substrate SUB2. In addition, among the lights emitted from the light emitting element LED, a second light L2 may pass through the second substrate SUB2 without being reflected by the second substrate SUB2.

In a case where the liquid crystal layer LCL is not disposed between the first substrate SUB1 and the second substrate SUB2, the first light L1 and the second light L2 may cause interference after passing through the second substrate SUB2. In this case, rainbow stains may be recognized in the display area DA.

In an embodiment of the invention, as the liquid crystal layer LCL is disposed between the first substrate SUB1 and the second substrate SUB2, an optical path of lights incident on the second substrate SUB2 becomes more random, coherence can be reduced, such that visibility of rainbow stains in the display area DA can be reduced.

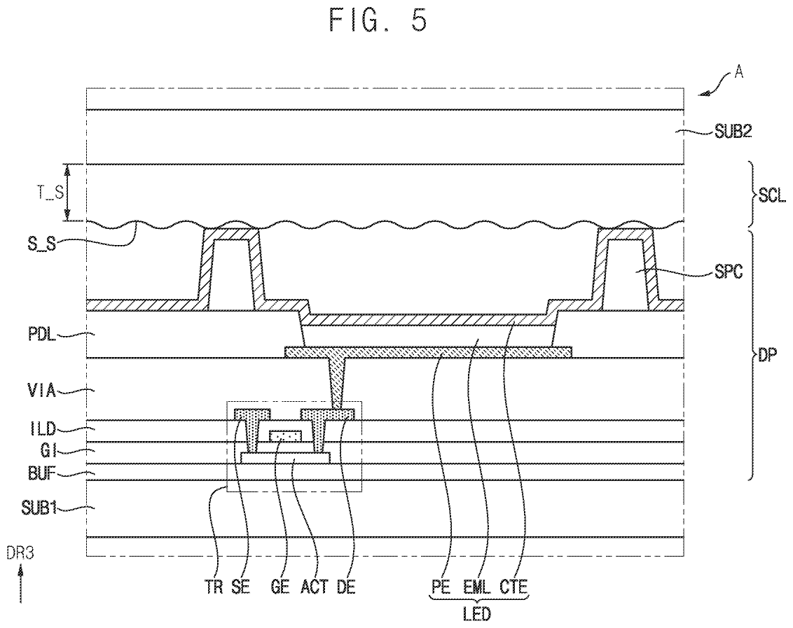

FIGS. 5, 6, and 7 are cross-sectional views illustrating area A of FIG. 2 according to alternative embodiments of the disclosure.

Referring to FIGS. 5, 6, and 7, a display device according to an alternative embodiment of the disclosure may include the first substrate SUB1, the display portion DP, a scattering layer SCL, and the second substrate SUB2. In such an embodiment, the display portion DP may include the buffer layer BUF, the transistor TR, the gate insulating layer GI, the interlayer insulating layer ILD, the via insulating layer VIA, and the pixel defining layer PDL, the light emitting element LED, and the spacer SPC. The display device shown in FIGS. 5, 6, and 7 may be substantially the same as or similar to the display device DD described with reference to FIGS. 3 and 4 except for the scattering layer SCL. Hereinafter, any repetitive detailed descriptions of the same or like elements as those described above will be omitted or simplified.

In an embodiment, the scattering layer SCL may be disposed between the display portion DP and the second substrate SUB2. In such an embodiment, the scattering layer SCL may contact one surface of the second substrate SUB2. The one surface of the second substrate SUB2 may face the first substrate SUB1. In such an embodiment, a scattering effect can be obtained. In an embodiment, for example, the scattering layer SCL may include an organic material having light transmittance.

In an embodiment, as illustrated in FIG. 5, a surface S_S of the scattering layer SCL facing the first substrate SUB1 may have a concavo-convex shape. In such an embodiment, the scattering layer SCL may include the base resin BS and may not include scattering particles.

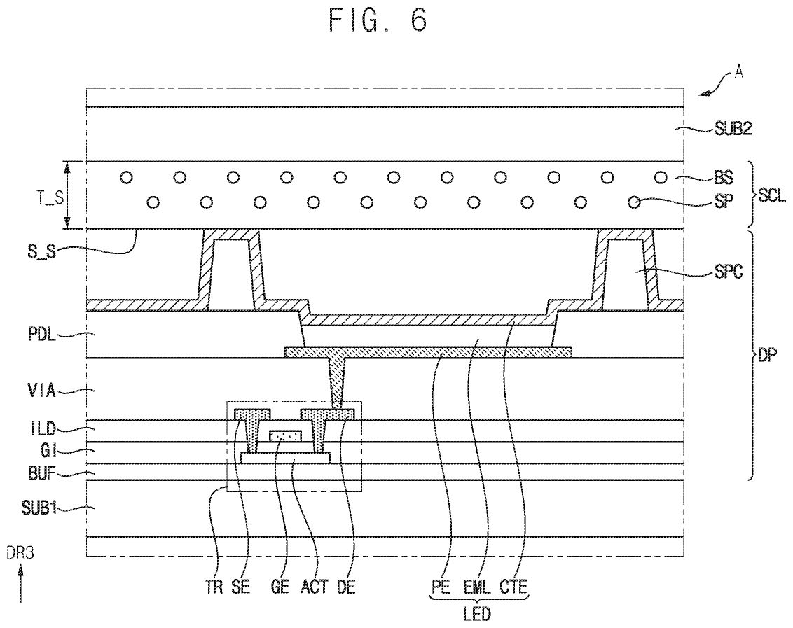

In an alternative embodiment, as illustrated in FIG. 6, the scattering layer SCL may include the base resin BS and a plurality of scattering particles SP dispersed in the base resin BS. In such an embodiment, the surface S_S of the scattering layer SCL facing the first substrate SUB1 may be substantially flat. In an embodiment, for example, each of the plurality of scattering particles SP may include an inorganic material such as TiO₂, Sb₂O₃, CaO, In₂O₃, or the like. These may be used alone or in combination with each other. However, embodiments of the disclosure are not limited thereto.

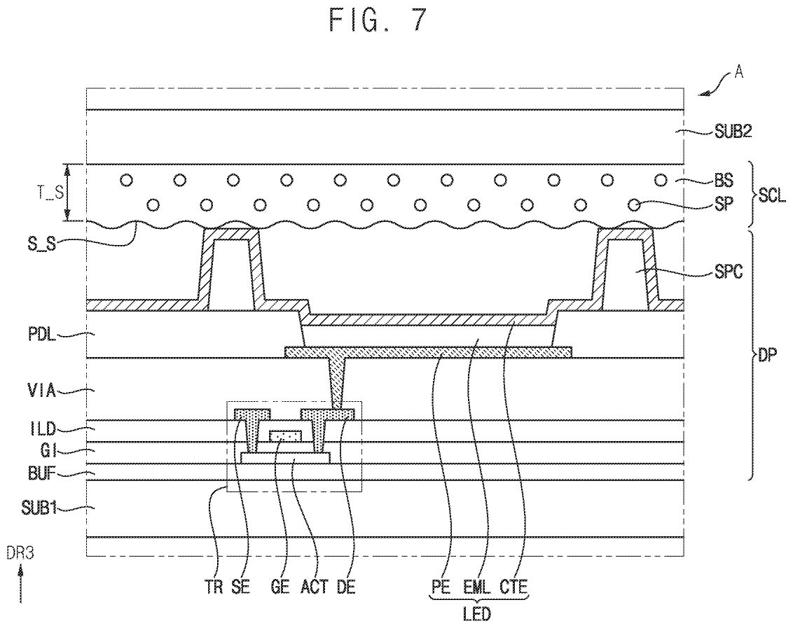

In another alternative embodiment, as illustrated in FIG. 7, the scattering layer SCL may include the base resin BS and the plurality of scattering particles SP dispersed in the base resin BS, and the surface S_S of the scattering layer SCL facing the first substrate SUB1 may have a concavo-convex shape.

In an embodiment, for example, in the case of FIGS. 5 and 7, the scattering layer SCL may be coated on the one surface of the second substrate SUB2, and the surface S_S of the scattering layer SCL may have a concavo-convex shape through an etching process, an ashing process, or a plasma process.

In an embodiment, for example, an average thickness T_S of the scattering layer SCL may be in a range from about 1000 nm to about 3000 nm. However, embodiments of the disclosure are not limited thereto.

In such an embodiment, as the scattering layer SCL is disposed between the first substrate SUB1 and the second substrate SUB2, an optical path of light incident on the second substrate SUB2 becomes more random, coherence can be reduced, such that visibility of rainbow stains in the display area DA can be reduced.

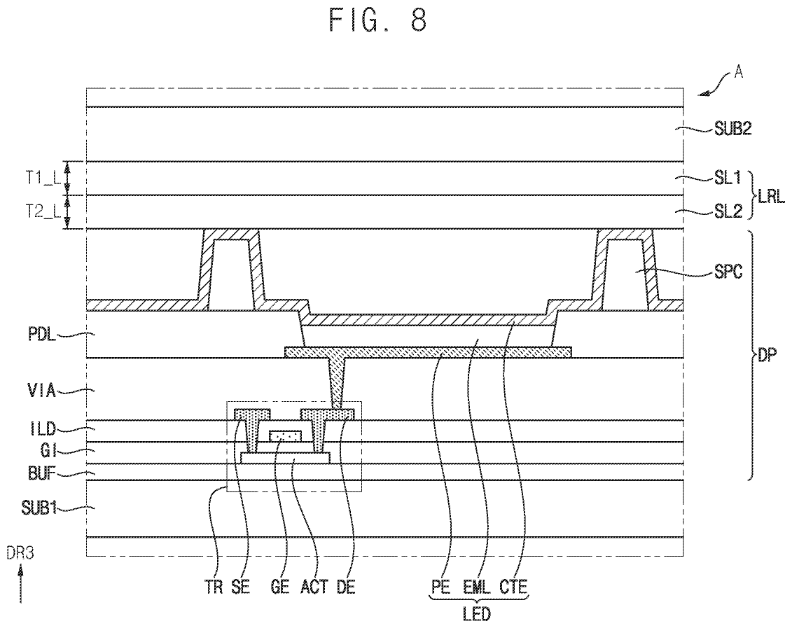

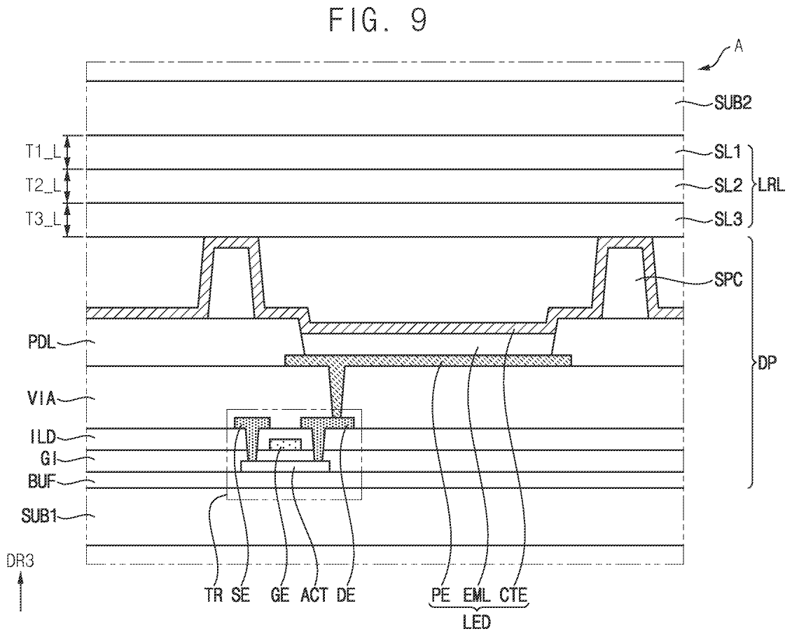

FIGS. 8 and 9 are cross-sectional views illustrating area A of FIG. 2 according to other alternative embodiments of the disclosure.

Referring to FIGS. 8 and 9, a display device according to another alternative embodiment of the disclosure may include the first substrate SUB1, the display portion DP, a low-reflection layer LRL, and the second substrate SUB2. In such an embodiment, the display portion DP may include the buffer layer BUF, the transistor TR, the gate insulating layer GI, the interlayer insulating layer ILD, the via insulating layer VIA, and the pixel defining layer PDL, the light emitting element LED, and the spacer SPC.

The display device shown in FIGS. 8 and 9 may be substantially the same as or similar to the display device DD described with reference to FIGS. 3 and 4 except for the low-reflection layer LRL. Hereinafter, any repetitive detailed descriptions of the same or like elements as those described above will be omitted or simplified.

In an embodiment, the low-reflection layer LRL may be disposed between the display portion DP and the second substrate SUB2. In such an embodiment, the low-reflection layer LRL may contact one surface of the second substrate SUB2. The low-reflection layer LRL may have a multi-layer structure in which a plurality of sub-layers are stacked.

In an embodiment, for example, as shown in FIG. 8, the low-reflection layer LRL may have a two-layer structure in which a first sub-layer SL1 and a second sub-layer SL2 are sequentially stacked. Alternatively, as shown in FIG. 9, the low-reflection layer LRL may have a three-layer structure in which the first sub-layer SL1, the second sub-layer SL2, and a third sub-layer SL3 are sequentially stacked. However, embodiments of the disclosure are not limited thereto.

In an embodiment, the plurality of sub-layers of the low-reflection layer LRL may have different refractive indices, respectively, in a visible ray area. However, embodiments of the disclosure are not limited thereto, and some sub-layers among the plurality of sub-layers of the low-reflection layer LRL may have a same refractive indices as each other in the visible ray area.

In an embodiment, the refractive index of each of the plurality of sub-layers of the low reflection layer LRL in the visible ray area may be in a range from about 1.0 to about 1.9. In an embodiment illustrated in FIGS. 8 and 9, for example, the refractive index of each of the first, second, and third sub-layers SL1, SL2, and SL3 in the visible ray area may be in a range from about 1.0 to about 1.9.

In an embodiment, the thickness of each of the plurality of sub-layers of the low-reflection layer LRL may be in a range from about 10 nm to about 900 nm. In an embodiment, for example, the thickness of each of the plurality of sub-layers of the low-reflection layer LRL may be in a range from about 50 nm to about 180 nm. In an embodiment illustrated in FIGS. 8 and 9, for example, the thicknesses T1_L, T2_L, and T3_L of each of the first, second, and third sub-layers SL1, SL2, and SL3 may be in a range from about 10 nm to about 900 nm.

In an embodiment, for example, the low-reflection layer LRL may include an inorganic material and/or an organic material having light transmittance.

As the low reflection layer LRL is disposed between the first substrate SUB1 and the second substrate SUB2, reflection of light incident on the second substrate SUB2 can be minimized to reduce coherence, such that visibility of rainbow stains in the display area DA can be reduced.

Referring back to FIGS. 3, 4, 5, 6, 7, 8, and 9, in an embodiment, any one of the liquid crystal layer LCL, the scattering layer SCL, and the low-reflection layer LRL may be disposed between the first substrate SUB1 and the second substrate SUB2. Accordingly, visibility of rainbow stains in the display area DA can be reduced.

Embodiments of the disclosure can be applied to various display devices, for example, display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first substrate;
a display portion disposed on the first substrate;
a second substrate disposed on the display portion; and
a liquid crystal layer contacting one surface of the second substrate, wherein the liquid crystal layer includes a plurality of liquid crystal molecules,
wherein a surface of the liquid crystal layer facing the first substrate has a concavo-convex shape.

2. The display device of claim 1, wherein the plurality of liquid crystal molecules are vertically aligned with respect to the one surface of the second substrate.

3. The display device of claim 1, wherein the plurality of liquid crystal molecules are randomly aligned horizontally with respect to the one surface of the second substrate.

4. The display device of claim 1, further comprising:
a sealing portion disposed between the first substrate and the second substrate along an edge of each of the first substrate and the second substrate, wherein the sealing portion couples the first substrate and the second substrate to each other.

5. The display device of claim 1, wherein each of the first substrate and the second substrate includes a glass substrate.

6. The display device of claim 1, wherein an average thickness of the liquid crystal layer is in a range from about 1000 nm to about 3000 nm.

7. A display device comprising:
a first substrate;
a display portion disposed on the first substrate;
a second substrate disposed on the display portion; and
a scattering layer contacting one surface of the second substrate.

8. The display device of claim 7, wherein the scattering layer includes a base resin and a plurality of scattering particles dispersed in the base resin.

9. The display device of claim 8, wherein a surface of the scattering layer facing the first substrate is substantially flat.

10. The display device of claim 7, wherein a surface of the scattering layer facing the first substrate has a concavo-convex shape.

11. The display device of claim 7, wherein
the scattering layer includes a base resin and a plurality of scattering particles dispersed in the base resin, and
a surface of the scattering layer facing the first substrate has a concavo-convex shape.

12. The display device of claim 7, wherein the scattering layer includes an organic material having light transmittance.

13. The display device of claim 7, further comprising:
a sealing portion disposed between the first substrate and the second substrate along an edge of each of the first substrate and the second substrate, wherein the sealing portion couples the first substrate and the second substrate to each other.

14. The display device of claim 7, wherein each of the first substrate and the second substrate includes a glass substrate.

15. A display device comprising:
a first substrate;
a display portion disposed on the first substrate;
a second substrate disposed on the display portion; and
a low-reflection layer contacting one surface of the second substrate, wherein the low-reflection layer has a multi-layer structure, in which a plurality of sub-layers are stacked.

16. The display device of claim 15, wherein the low-reflection layer has the multi-layer structure including two or three sub-layers.

17. The display device of claim 15, wherein the sub-layers of the low-reflection layer have different refractive indices from each other.

18. The display device of claim 15, wherein a refractive index of each of the sub-layers of the low-reflection layer is in a range from about 1.0 to about 1.9.

19. The display device of claim 15, wherein a thickness of each of the sub-layers of the low-reflection layer is in a range from about 10 nm and about 900 nm.

20. The display device of claim 15, wherein the low-reflection layer includes at least one material selected from an inorganic material and an organic material having light transmittance.
